(19) United States
(12) Patent Application Publication
(10) Pub. No.: US 2024/0136392 A1
(43) Pub. Date: Apr. 25, 2024

(54) MEMORY DEVICES, COMPONENTS THEREOF, AND RELATED METHODS AND SYSTEMS

(71) Applicant: ASM IP Holding B.V., Almere (NL)

(72) Inventors: Alessandra Leonhardt, Sipoo (FI); Michael Eugene Givens, Oud-Heverlee (BE); Giuseppe Alessio Verni, Vantaa (FI); Qi Xie, Shanghai (CN)

(21) Appl. No.: 18/491,779

(22) Filed: Oct. 21, 2023

Related U.S. Application Data
(60) Provisional application No. 63/380,773, filed on Oct. 25, 2022.

(51) Int. Cl. H10B 12/10

(52) U.S. Cl. CPC H01L 28/75

(57) ABSTRACT

Methods of processing a substrate and related structures and systems. Described methods comprise forming a distal dipole layer on to a distal material layer; forming a high-k dielectric on the distal dipole layer; and, forming a proximal dipole layer on the high-k dielectric.

### CROSS-REFERENCE TO RELATED APPLICATION(S)

This Application claims the benefit of U.S. Provisional Application 63/380,773 filed on Oct. 25, 2022, the entire contents of which are incorporated herein by reference.

### FIELD OF INVENTION

The present disclosure generally relates to the field of semiconductor processing methods and systems, and to the field integrated circuit manufacture. In particular, memory elements, components thereof, and methods and systems suitable for forming memory elements and programmable logic devices are disclosed herein.

### BACKGROUND OF THE DISCLOSURE

Next generation metal-insulator-metal (MIM) capacitors for both logic and memory applications are strongly affected by leakage current. Therefore, reducing the leakage current becomes a critical aspect of being able to scale down the dimensions on the dielectric thus achieving high capacitance densities. Some strategies have been proposed in literature. However, those alternatives have their own drawbacks. Thus, there is a need for improved ways to reduce leakage currents in MIM capacitors.

The following documents are made of record:
Song, H., et al., Thin Solid Films 713 (2020) 138368 discloses an Al₂O₃ blocking layer inserted ZrO₂ Metal-Insulator-Metal capacitor for the improved electrical and interfacial properties.
Kirsch, P. D., et al., Appl. Phys. Lett. 92, 092901 (2008) discloses a dipole model explaining high-k/metal gate field effect transistor threshold voltage tuning.
Chang, T., et al., ACS Appl. Electron. Mater. 2019, 1, 1091-1098 discloses High-K Gate Dielectrics Treated with in Situ Atomic Layer Bombardment.
Popovici, M., et al. 2018 IEEE International Electron Devices Meeting (IEDM). IEEE, 2018. Discloses a High-performance (EOT<0.4 nm, Jg˜10⁻⁷ A/cm²) ALD-deposited Ru\SrTiO₃ stack for next generations DRAM pillar capacitor.
Huang, AnPing, et al. Chinese Science Bulletin 57.22 (2012): 2872-2878. discloses methods for Interface dipole engineering in metal gate/high-k stacks.
JP6145756 B2 discloses a MOSFET with polarizable interface dipole as non-volatile storage element.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to structures that comprise a proximal material layer; a proximal dipole layer adjacent to the proximal material layer; a high-k dielectric adjacent to the proximal dipole layer; a distal dipole layer adjacent to the high-k dielectric; and a distal material layer adjacent to the distal dipole layer.

In some embodiments, the electric potential decreases towards the high-k dielectric.

In some embodiments the electric potential increases towards the high-k dielectric.

In some embodiments, the proximal dipole layer and the distal dipole layer comprise an element selected from the list consisting of element selected from the list consisting of magnesium (Mg), erbium (Er), strontium (Sr), scandium (Sc), yttrium (Y), lanthanum (La), and cerium (Ce).

In some embodiments, the proximal dipole layer and the distal dipole layer comprise an element selected from the list consisting of vanadium (V), aluminum (Al), nickel (Ni), and tin (Sn).

Further described herein is a method of forming a structure. The method comprises providing a substrate to a reaction chamber. The substrate comprises a distal material layer. The method further comprises forming a distal dipole layer on to the distal material layer. The method further comprises forming a high-k dielectric on the distal dipole layer. The method further comprises forming a proximal dipole layer on the high-k dielectric.

In some embodiments, forming the distal dipole layer comprises executing a distal dipole cyclical deposition process. The distal dipole cyclical deposition process comprises one or more distal dipole cycles. A distal dipole cycle comprises consecutively executing a distal dipole precursor pulse and a distal dipole oxidant pulse. The distal dipole precursor pulse comprises contacting the substrate with a distal dipole precursor. The distal dipole oxidant pulse comprises contacting the substrate with a distal dipole oxidant.

In some embodiments, the distal dipole cyclical deposition process comprises from at least 3 to at most 5 distal dipole cycles.

In some embodiments, forming the proximal dipole layer comprises executing a proximal dipole cyclical deposition process. The proximal dipole cyclical deposition process comprises one or more proximal dipole cycles. A proximal dipole cycle comprises consecutively executing a proximal dipole precursor pulse and a proximal dipole oxidant pulse. The proximal dipole precursor pulse comprises contacting the substrate with a proximal dipole precursor. The proximal dipole oxidant pulse comprises contacting the substrate with a proximal dipole oxidant.

In some embodiments, the proximal dipole cyclical deposition process comprises from at least 3 to at most 5 proximal dipole cycles.

In some embodiments, at least one of the distal dipole precursor and the proximal dipole precursor is selected from a scandium precursor, a lanthanum precursor, a cerium precursor, and an yttrium precursor.

In some embodiments, the method further comprises a step of annealing the substrate.

In some embodiments, at least one of the distal dipole precursor and the proximal dipole precursor comprise one or more precursors selected from the list consisting of a vanadium precursor, an aluminum precursor, a nickel precursor, and a tin precursor.

In some embodiments, at least one of the distal dipole precursor and the proximal dipole precursor comprises one or more precursors selected from the list consisting of a scandium precursor, a strontium precursor, a lanthanum precursor, a cerium precursor, and an yttrium precursor.

In some embodiments, the method further comprises a step of forming a proximal material layer on the proximal dipole layer.

In some embodiments, at least one of the distal dipole layer and the proximal dipole layer comprises a material selected from the list consisting of scandium oxide, strontium oxide, lanthanum oxide, cerium oxide, and yttrium oxide.

In some embodiments, at least one of the distal dipole layer and the proximal dipole layer comprises a material selected from the list consisting of aluminum oxide, vanadium oxide, tin oxide, and nickel oxide.

In some embodiments, at least one of the distal material layer and the proximal material layer comprises a transition metal nitride.

Further described herein is a system. The system comprises one or more processing chambers; a hafnium precursor source comprising a hafnium precursor; a zirconium precursor source comprising a zirconium precursor; a dipole precursor source comprising a dipole precursor; an oxygen reactant source comprising an oxygen reactant; and a controller. The controller is configured to control gas flow into the one or more processing chambers and to process a substrate by means of a method as described herein.

In some embodiments, forming the distal dipole layer, forming the high-k dielectric, and forming the proximal dipole layer is done in a single reaction chamber, without any intervening vacuum break.

These and other embodiments will become readily apparent to those skilled in the art from the following detailed description of certain embodiments having reference to the attached figures. The invention is not limited to any particular embodiments disclosed.

### BRIEF DESCRIPTION OF THE DRAWING FIGURES

A more complete understanding of the embodiments of the present disclosure may be derived by referring to the detailed description and claims when considered in connection with the following illustrative figures.

FIGS. 1A-1D show four band diagrams.

FIGS. 2A-D schematically show the physical structures that give rise to the band diagrams of FIGS. 1A-1D.

FIGS. 3 and 4 show experimental current-voltage (IV) characteristics

FIG. 5 shows an embodiment of a method as described herein.

FIG. 6 schematically shows a process flow of an embodiment of a method for forming a dipole layer or for forming a high-k dielectric as described herein.

FIG. 7 schematically shows a process flow according to another embodiment of a method as described herein.

FIG. 8 illustrates a system (800) in accordance with exemplary embodiments of the disclosure.

FIG. 9 schematically shows a system (900) comprising a first process chamber (910), a second process chamber (920), and a third process chamber (930).

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

The description of exemplary embodiments of methods, structures, devices and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas. Precursors and reactants can be gasses. Exemplary seal gasses include noble gasses, nitrogen, and the like. In some cases, the term “precursor” can refer to a compound that participates in the chemical reaction that produces another compound, and particularly to a compound that constitutes a film matrix or a main skeleton of a film; the term “reactant” can be used interchangeably with the term precursor.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The substrate may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e. ceramic fibers or polymer fibers). Continuous substrates may also comprise carriers or sheets upon which non-continuous substrates are mounted.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may comprise, or may consist at least partially of, a plurality of dispersed atoms on a surface of a substrate and/or may be or may become embedded in a substrate and/or may be or may become embedded in a device manufactured on that substrate. A film or layer may comprise material or a layer with pinholes and/or isolated islands. A film or layer may be at least partially continuous. A film or layer may be patterned, e.g. subdivided, and may be comprised in a plurality of semiconductor devices. A film or layer may be selectively grown on some parts of a substrate, and not on others.

The term “deposition process” as used herein can refer to the introduction of precursors (and/or reactants) into a reaction chamber to deposit a layer over a substrate. “Cyclical deposition processes” are examples of “deposition processes”.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es). A pulse can comprise exposing a substrate to a precursor or reactant. This can be done, for example, by introducing a precursor or reactant to a reaction chamber in which the substrate is present. Additionally or alternatively, exposing the substrate to a precursor can comprise moving the substrate to a location in a substrate processing system in which the reactant or precursor is present.

Generally, for ALD processes, during each cycle, a precursor is introduced into a reaction chamber and is chemisorbed onto a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, the term “purge” may refer to a procedure in which an inert or substantially inert gas is provided to a reaction chamber in between two pulses of gasses that react with each other. For example, a purge, e.g. using a noble gas, may be provided between a precursor pulse and a reactant pulse, thus avoiding or at least minimizing gas phase interactions between the precursor and the reactant. It shall be understood that a purge can be effected either in time or in space, or both. For example in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example in the case of spatial purges, a purge step can take the following form: moving a substrate from a first location to which a first precursor is continually supplied, through a purge gas curtain, to a second location to which a second precursor is continually supplied.

As used herein, a “precursor” includes a gas or a material that can become gaseous and that can be represented by a chemical formula that includes an element which may be incorporated during a deposition process as described herein.

The term “oxygen reactant” can refer to a gas or a material that can become gaseous and that can be represented by a chemical formula that includes oxygen. In some cases, the chemical formula includes oxygen and hydrogen.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like.

As used herein, the term “comprising” indicates that certain features are included, but that it does not exclude the presence of other features, as long as they do not render the claim or embodiment unworkable. In some embodiments, the term “comprising” includes “consisting”. As used herein, the term “consisting” indicates that no further features are present in the apparatus/method/product apart from the ones following said term. When the term “consisting” is used referring to a chemical compound, it indicates that the chemical compound only contains the components which are listed.

As used herein, “distal” can refer to the side of a structure that is close to a substrate, and “proximal” can refer to the side of a structure that is more distant from the substrate.

In this disclosure, any defined meanings do not necessarily exclude ordinary and customary meanings, in some embodiments.

Described herein is a structure. In some embodiments, the structure comprises a proximal material layer. The structure further comprises a proximal dipole layer which is adjacent to the proximal material layer. The structure further comprises a high-k dielectric layer adjacent to the proximal dipole layer. The structure further comprises a distal dipole layer which is adjacent to the high-k dielectric. The structure further comprises a distal material which is adjacent to the distal dipole layer.

A structure as described herein can thus comprise a high-k dielectric, also called high-k dielectric layer, which is sandwiched between two dipole layers: a proximal dipole layer and a distal dipole layer. The proximal dipole layer and the distal dipole layer are contacted by a proximal material layer and a distal material layer, respectively.

In some embodiments, the high-k dielectric can be a ferroelectric layer. In some embodiments, the ferroelectric layer can have a fluorite structure.

Structures and methods as described herein advantageously allow obtaining metal-insulator-metal capacitors having a low leakage current.

In some embodiments, a structure as described herein can be employed as, or as one or more constituent parts of, a metal-insulator-metal capacitor, a ferroelectric random access memory, a ferroelectric field effect transistor, and a ferroelectric tunnel junction.

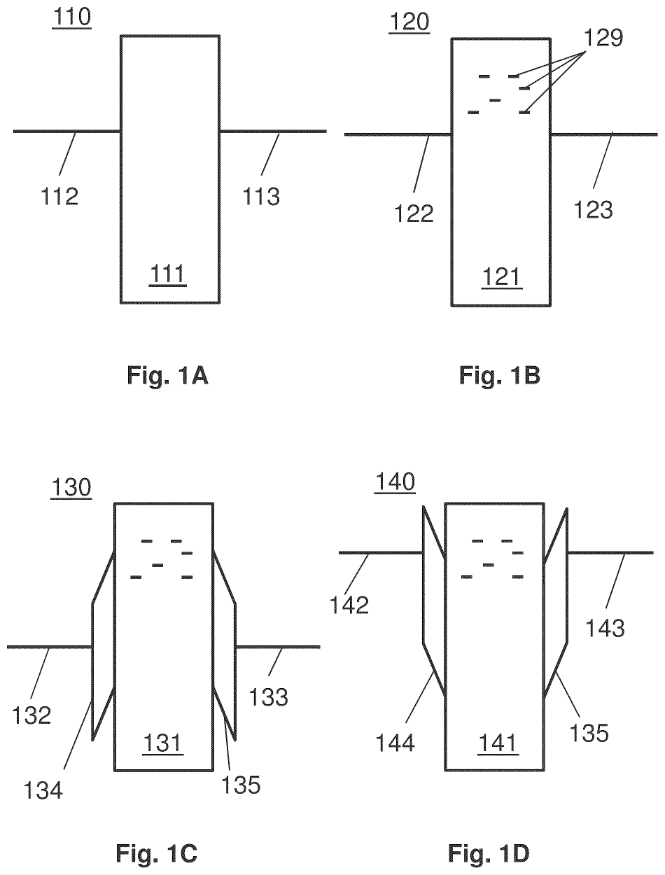

In some embodiments, the electric potential decreases towards the high-k dielectric. In other words, the electric potential can decrease through the proximal dipole layer towards the high-k dielectric and through the distal dipole layer towards the high-k dielectric. Such a structure is shown in FIG. 1C. Such a structure results in an increased electron barrier and a reduced hole barrier between the distal material layer and the proximal material layer, vis-à-vis a structure without dipole layers. Such a structure features upwards band bending towards the high-k dielectric, in a classical electron energy band diagram. In such a structure, the dipole moments in the proximal and distal dipole layers point towards the high-k dielectric. In such embodiments, the proximal and distal dipole layers can suitable be n-type dipole layers.

Suitable n-type dipole layers can comprise an element selected from the list consisting of magnesium (Mg), erbium (Er), strontium (Sr), scandium (Sc), yttrium (Y), lanthanum (La), and cerium (Ce). Such dipole layers can comprise one or more of scandium oxide, yttrium oxide, lanthanum oxide, and cerium oxide. In some embodiments, the proximal dipole layer and the distal dipole layer comprise an element selected from the list consisting of magnesium (Mg), erbium (Er), strontium (Sr), scandium (Sc), yttrium (Y), lanthanum (La), and cerium (Ce).

Suitable p-type dipole layers can comprise nickel (Ni), gallium (Ga), niobium (Nb), molybdenum (Mo), vanadium (V), aluminum (Al), and tin (Sn). Such dipole layers can comprise at least one of nickel oxide, gallium oxide, niobium oxide, molybdenum oxide, aluminum oxide, vanadium oxide, and tin oxide. In some embodiments, the proximal dipole layer and the distal dipole layer comprise an element selected from nickel (Ni), gallium (Ga), niobium (Nb), molybdenum (Mo), aluminum (Al), tin (Sn), and vanadium (V).

In some embodiments, the electrical potential increases towards the high-k dielectric. In other words, the electric potential can increase through the proximal dipole layer towards the high-k dielectric and through the distal dipole layer towards the high-k dielectric. Such a structure is shown in FIG. 1D. Without wishing to be bound by any particular theory or mode of operation, it is believed that such a structure results in an increased hole barrier and a reduced electron barrier between the distal material layer and the proximal material layer, vis-h-vis a structure without dipole layers. Such a structure features downwards band bending towards the high-k dielectric, in a classical electron energy band diagram. In such a structure, the dipole moments in the proximal and distal dipole layers point away from the high-k dielectric. In such embodiments, the proximal and distal dipole layers can suitable be p-type dipole layers.

In some embodiments, at least one of the distal material layer and the proximal material layer comprises a semiconductor. In some embodiments, the distal material layer comprises a semiconductor. In some embodiments, the proximal material layer comprises a semiconductor. In some embodiments, the distal material layer and the proximal material layer comprise a semiconductor.

Suitable semiconductors include semiconducting oxides. The semiconducting oxides can be degenerate or non-degenerate. The semiconducting oxides can exhibit n-type conductivity or p-type conductivity. In some embodiments, the semiconducting oxide comprises doped or undoped indium-gallium-zinc-oxide. In some embodiments, the semiconducting oxide is selected from the list consisting of vanadium oxide, indium oxide, and indium tin oxide. It shall be understood that indium gallium zinc oxide can refer to a material comprising gallium, zinc, indium, oxygen, and optionally further elements such as dopant elements. It shall be understood that indium tin oxide can refer to a material comprising indium, tin, oxygen, and optionally further elements such as dopant elements. In some embodiments, the semiconducting oxide comprises ruthenium oxide.

In some embodiments, at least one of the distal material layer and the proximal material layer comprises a metal. In some embodiments, the distal material layer comprises a metal. In some embodiments, the proximal material layer comprises a metal. In some embodiments, the distal material layer and the proximal material layer comprise a metal. Suitable metals include ruthenium, cobalt, iridium, platinum, tungsten and molybdenum.

In some embodiments, at least one of the distal material layer and the proximal material layer comprises a metal nitride. Suitable metal nitrides include transition metal nitrides such as titanium nitride.

In some embodiments, the distal material layer comprises a metal and the proximal material layer comprises a semiconductor. Suitable semiconductors include semiconducting oxides. Suitable semiconducting oxides include indium gallium zinc oxide, indium tin oxide, nickel oxide, and cuprous oxide.

In some embodiments, at least one of the distal material layer and the proximal material layer comprises a transition metal nitride. Suitable transition metal nitrides include titanium nitride and tantalum nitride.

In some embodiments, the distal dipole layer has a different composition than the proximal dipole layer.

In some embodiments, the distal dipole layer and the proximal dipole layer have an identical composition.

In some embodiments, at least one of the distal dipole layer and the proximal dipole layer comprise a material selected from the list consisting of scandium oxide, strontium oxide, lanthanum oxide, cerium oxide, and yttrium oxide. These can be described as dielectric dipole layers. Dipole layers containing such materials can be advantageously employed as n-type dipole layers. Since these materials are dielectric layers, their use can potentially result in equivalent oxide thickness (EOT) increase. But since the function of the dipole is simply to generate a difference in the electronegativity in the interface between the high-k dielectric and its electrodes (i.e. the material layers), extremely thin layers can be employed. They can be deposited using ALD processes which are as such known in the Art. Even a few ALD cycles (1-5 cycles) can already result sufficiently strong dipoles to induce some band shifting. Additionally, many of those layers have a dielectric constant close to 20 or even higher, which allows avoiding/reducing the drawback of equivalent oxide thickness (EOT) increase.

In some embodiments, at least one of the distal dipole layer and the proximal dipole layer comprises a material selected from the list consisting of aluminum oxide, vanadium oxide, tin oxide, and nickel oxide. Dipole layers containing such materials can be advantageously used as p-type dipole layers. Advantageously, some of these materials are conductive oxides, which can allow band shifting of without an equivalent oxide thickness increase, in particular in the case of metal-insulator-metal capacitors in which both the distal and proximal electrodes are metallic. They can be deposited using ALD processes which are as such known in the Art.

Further described herein is a method of forming a structure. In some embodiments, the structure is a structure as described herein. The method comprises providing a substrate to a reaction chamber. The substrate comprises a distal material layer. The method further comprises forming a distal dipole layer on to the distal material layer. The method further comprises forming a high-k dielectric on the distal dipole layer. The method further comprises forming a proximal dipole layer on the high-k dielectric.

The dipole layers can be conductive or dielectric. Thus, in some embodiments, at least one of the proximal dipole layer and the distal dipole layer is conductive. Additionally or alternatively, at least one of the proximal dipole layer and the distal dipole layer can be a dielectric layer.

In some embodiments, forming at least one of the distal dipole layer and the proximal dipole layer comprises executing a cyclical deposition process. Suitable cyclical deposition processes include atomic layer deposition (ALD).

In some embodiments, forming the distal dipole layer comprises executing a distal dipole cyclical deposition process. The distal dipole cyclical deposition process comprises one or more distal dipole cycles. A distal dipole cycle comprises consecutively executing a distal dipole precursor pulse and a distal dipole oxidant pulse. The distal dipole precursor pulse comprises contacting the substrate with a distal dipole precursor. The distal dipole oxidant pulse comprises contacting the substrate with a distal dipole oxidant.

In some embodiments, forming the proximal dipole layer comprises executing a proximal dipole cyclical deposition process. The proximal dipole cyclical deposition process comprises one or more proximal dipole cycles. A proximal dipole cycle comprises consecutively executing a proximal dipole precursor pulse and a proximal dipole oxidant pulse. The proximal dipole precursor pulse comprises contacting the substrate with a proximal dipole precursor. The proximal dipole oxidant pulse comprises contacting the substrate with a proximal dipole oxidant.

The distal and proximal dipole cyclical deposition processes can be the same, or they can be different. They can any suitable number of cycles, for example from at least 1 to at most 1000 cycles, or from at least 1 to at most 5 cycles, or from at least 5 to at most 20 cycles, or from at least 20 to at most 100 cycles, or from at least 100 to at most 500 cycles, or from at least 500 to at most 1000 cycles. In some embodiments, the proximal and distal cyclical dipole processes have more than one and less than ten cycles.

In some embodiments, the distal dipole cyclical deposition process comprises from at least 3 to at most 5 distal dipole cycles.

In some embodiments, the proximal dipole cyclical deposition process comprises from at least 3 to at most 5 proximal dipole cycles.

In some embodiments, forming the distal dipole layer, forming the high-k dielectric layer, and forming the proximal dipole layer is done in one and the same reaction chamber. Alternatively, the distal dipole layer and the proximal dipole layer can be formed in a first reaction chamber, and the high-k dielectric layer can be formed in a second reaction chamber. It shall be understood that the first reaction chamber and the second reaction chamber are comprised in the same vacuum system, that substrate transport between the reaction chambers can occur by means of a robot arm or other means, and that vacuum is not broken during transport between the first and second reaction chambers, i.e. that the substrate is maintained in a vacuum environment during transport between the two reaction chambers.

In some embodiments, the high-k dielectric layer may have a thickness of from at least 0.5 nm to at most 10.0 nm or of at least 1.0 nm to at most 8.0 nm, or of at least 2.0 nm to at most 6.0 nm, or of at least 3.0 nm to at most 4.0 nm.

In some embodiments, at least one of the proximal dipole layer and the distal dipole layer has a thickness of at least 0.1 nm to at most 0.5 nm.

In some embodiments, forming the high-k dielectric layer comprises executing a plurality of high-k dielectric deposition cycles. A high-k dielectric deposition cycle can comprise one or more high-k dielectric precursor pulses and one or more oxygen reactant pulses. The high-k dielectric precursor pulses comprise exposing the substrate to a precursor. The oxygen reactant pulses comprise exposing the substrate to an oxygen reactant. Thus, a high-k dielectric layer is formed.

In some embodiments, a high-k dielectric deposition cycle comprises exposing the substrate to a hafnium precursor in a hafnium precursor pulse and to an oxygen reactant in an oxygen reactant pulse. Thus, a high-k dielectric comprising hafnium oxide can be formed.

In some embodiments, a high-k deposition cycle comprises exposing the substrate to a hafnium precursor in a hafnium precursor pulse, exposing the substrate to a zirconium precursor in a zirconium precursor pulse, and exposing the substrate to an oxygen reactant in an oxygen reactant pulse. Thus, a high-k dielectric layer comprising hafnium zirconium oxide can be formed.

In some embodiments, least one of the distal dipole precursor and the proximal dipole precursor is selected from a magnesium precursor, an erbium precursor, a strontium precursor, scandium precursor, a lanthanum precursor, a cerium precursor, and an yttrium precursor. Thus, distal and proximal dipole layers comprising at least one of scandium, lanthanum, cerium, and yttrium can be formed. Those dipole layers can suitably function as n-type dipole layers.

In some embodiments, least one of the distal dipole precursor and the proximal dipole precursor is selected from a vanadium precursor, an aluminum precursor, a nickel precursor, and a tin precursor. Thus, distal and proximal dipole layers comprising at least one of vanadium, aluminum, nickel, and tin can be made. Such dipole layers can suitably function as p-type dipole layers.

In some embodiments, the hafnium precursor comprises Hafnium in a +4 oxidation state.

In some embodiments, the hafnium precursor comprises one or more ligands selected from alkylamido ligands, alkoxy ligands, cyclopentadienyl ligands, beta-diketonate ligands, alkyl ligands, amidinate ligands, and halide ligands.

In some embodiments, the hafnium precursor can comprise at least one of an alkylamido ligand and an dialkylamido ligand. Suitable hafnium alkylamines include tetrakis(dimethylamino)hafnium, tetrakis(diethylamino)hafnium, and tetrakis(ethylmethylamino)hafnium.

In some embodiments, the hafnium precursor comprises a hafnium halide such as a hafnium chloride, a hafnium bromide, or a hafnium iodide. Suitable hafnium chlorides include HfCl₄. Suitable hafnium bromides include HfBr₄. Suitable hafnium iodides include Hfl₄.

In some embodiments, the hafnium precursor comprises a heteroleptic hafnium precursor. In some embodiments, the heteroleptic hafnium precursor comprises an unsubstituted or an alkyl-substituted hafnium cyclopentadienyl ligand. In some embodiments, the hafnium precursor comprises one or more alkylamido ligands. In some embodiments, the hafnium precursor comprises an alkylamido ligand and an unsubstituted or an alkyl-substituted cyclopentadienyl ligand. Suitable hafnium precursors include HfCp(NMe₂)₃, i.e. Tris(dimethylamino)cyclopentadienyl Hafnium.

In some embodiments, the zirconium precursor comprises Zirconium in a +4 oxidation state.

In some embodiments, the zirconium precursor comprises one or more ligands selected from the list consisting of alkylamido ligands, alkoxy ligands, cyclopentadienyl ligands, alkylcyclopetadienyl ligands, beta-diketonate ligands, alkyl ligands, amidinate ligands, and halide ligands.

In some embodiments, the zirconium precursor can comprise at least one of an alkylamido ligand and an dialkylamido ligand. Suitable zirconium alkylamines include tetrakis(dimethylamino)zirconium, tetrakis(diethylamino)zirconium, and tetrakis(ethylmethylamino)zirconium.

In some embodiments, the zirconium precursor comprises a heteroleptic zirconium precursor. In some embodiments, the heteroleptic zirconium precursor comprises an unsubstituted or an alkyl-substituted zirconium cyclopentadienyl ligand. In some embodiments, the zirconium precursor comprises one or more alkylamido ligands. In some embodiments, the zirconium precursor comprises an alkylamido ligand and an unsubstituted or an alkyl-substituted cyclopentadienyl ligand. Suitable zirconium precursors include ZrCp(NMe₂)₃, i.e. Tris(dimethylamino)cyclopentadienyl Zirconium.

In some embodiments, the dipole precursor comprises a compound that can be represented by the formula M(RCp)ₓ(L)_{y} wherein M is a rare earth metal, wherein R is selected from H, Me, Et, iPr, and tBu, and wherein L is selected from N,N′-diisopropylacetamidinate, N,N′-di-tert-butylacetamidinate, N,N′-diisopropylformamidinate, and N,N′-di-tert-butylformamidinate.

It shall be understood that Me stands for methyl, iPr stands for isopropyl, iPr-amd stands for N,N′-diisopropylacetamidinate, Et stands for ethyl, and Cp stands for cyclopentadienyl.

Suitable rare earth metals include lanthanum, cerium, and ytterbium.

In some embodiments, the lanthanum precursor comprises Lanthanum in a +4 oxidation state.

In some embodiments, the lanthanum precursor comprises one or more substituted or unsubstituted cyclopentadienyl ligand. Additionally or alternatively, the lanthanum precursor comprises one or more ligands selected from an alkylsilylamine, a diazadiene, and an amidinate.

In some embodiments, the lanthanum precursor comprises a heteroleptic precursor. Suitable heteroleptic precursors include precursors comprising one or more alkyl-substituted cyclopentadienyl ligands and one or more amidinate ligands, such as two alkyl-substituted cyclopentadienyl ligands and one amidinate ligand. Exemplary heteroleptic lanthanum precursors include La(MeCp)2(iPr-amd), La(EtCp)2(iPr-amd), La(iPrCP)2(iPr-amd).

In some embodiments, the lanthanum precursor comprises one or more ligands selected from the list consisting of alkylamido ligands, alkoxy ligands, cyclopentadienyl ligands, alkylcyclopetadienyl ligands, beta-diketonate ligands, alkyl ligands, amidinate ligands, and halide ligands.

In some embodiments, the lanthanum precursor comprises a compound that can be represented by the formula La(RCp)₂(L) wherein R is selected from H, Me, Et, iPr, and tBu, and wherein L is selected from N,N′-diisopropylacetamidinate, N,N′-di-tert-butylacetamidinate, N,N′-diisopropylformamidinate, and N,N′-di-tert-butylformamidinate.

In some embodiments, the lanthanum precursor comprises a lanthanum amidinate.

In some embodiments, the lanthanum precursor comprises Tris(isopropyl-cyclopentadienyl)lanthanum. In some embodiments, the lanthanum precursor comprises a substituted or unsubstituted cyclopentadienyl ligand. In some embodiments, the lanthanum precursor is selected from La(Cp)₃, La(EtCp)₃, La(MeCp)₃, La(nPrCp)₃, and La(nBuCp)₃. It shall be understood that Cp stands for cyclopentadienyl, that Et stands for ethyl, that Me stands for methyl, that nPr stands for n-propyl, and that nBu stands for n-butyl.

In some embodiments, the dipole precursor, such as at least one of the proximal dipole precursor and the distal dipole precursor, comprises a cerium precursor.

In some embodiments, the cerium precursor comprises Cerium in a +4 oxidation state.

In some embodiments, the cerium precursor comprises cerium in a +3 oxidation state.

In some embodiments, the cerium precursor comprises one or more ligands selected from alkylamido ligands, dialkylamido ligands, cyclopentadienyl ligands, alkylcyclopentadienyl ligands, amidinate ligands, beta-diketonate ligands, and alkoxide ligands.

In some embodiments, the cerium precursor comprises a compound that can be represented by the formula Ce(RCp)₂(L) wherein R is selected from H, Me, Et, iPr, and tBu, and wherein L is selected from N,N′-diisopropylacetamidinate, N,N′-di-tert-butylacetamidinate, N,N′-diisopropylformamidinate, and N,N′-di-tert-butylformamidinate.

In some embodiments, the dipole precursor, such as at least one of the proximal dipole precursor and the distal dipole precursor, comprises a scandium precursor.

In some embodiments, the scandium precursor comprises Scandium in a +4 oxidation state.

In some embodiments, the scandium precursor comprises scandium in a +3 oxidation state.

In some embodiments, the scandium precursor comprises one or more ligands selected from alkylamido ligands, dialkylamido ligands, cyclopentadienyl ligands, alkylcyclopentadienyl ligands, amidinate ligands, beta-dikeontate ligands, and alkoxide ligands.

In some embodiments, the scandium precursor comprises a cyclopentadienyl ligand such as tris(cyclopentadienyl)scandium.

In some embodiments, the scandium precursor comprises a cationic scandium amide complex. An example of such a precursor is Sc[N(SiHMe₂)₂]₃(THF), with Me standing for methyl and THF standing for tetrahydrofuran.

In some embodiments, the scandium precursor comprises an amidinate and an unsubstituted or alkyl-substituted cyclopentadienyl ligand. Examples such precursors include Sc(Cp)₂(Ni^{Pr} Me-amd), Sc(EtCp)₂(Ni^{Pr} Me-amd), and Sc(iPrCp)₂(Ni^{Pr} Me-amd). It shall be understood that Cp stands for cyclopentadienyl, iPr stands for isopropyl, Me stands for methyl, amd stands for amidinate, Ni^{Pr} indicates a nitrogen-bound isopropyl group. This precursor nomenclature is explained, and methods for producing such precursors are disclosed, in the United States patent application having publication no. US 2016/0315168 A1.

In some embodiments, the scandium precursor comprises a compound that can be represented by the formula Sc(RCp)₂(L) wherein R is selected from H, Me, Et, iPr, and tBu, and wherein L is selected from N,N′-diisopropylacetamidinate, N,N′-di-tert-butylacetamidinate, N,N′-diisopropylformamidinate, and N,N′-di-tert-butylformamidinate.

In some embodiments, the tin precursor comprises a tin alkyl such as trimethyl tin, triethyl tin, or triisopropyl tin.

In some embodiments, the strontium precursor comprises an alkyl-substituted cyclopentadienyl ligand such as bis(methylcyclopendadienyl)strontium(II), bis(ethylcyclopendadienyl)strontium(II), or bis(isopropylcyclopendadienyl)strontium(II).

In some embodiments, the vanadium precursor comprises a vanadium halide such as vanadium tetrachloride, a vanadium bromide, or a vanadiumiodide.

In some embodiments, the vanadium precursor comprises one or more alkylamino ligands. Exemplary vanadium precursors include tetrakis(dimethylamino)vanadium and tetrakis(diethylamino)vanadium.

In some embodiments, the oxygen reactant comprises one or more of H₂O, H₂O₂, O₂, O₃, N₂O, NO, and NO₂.

In some embodiments, a method as described herein further comprises a step of forming a proximal material layer on the proximal dipole layer. A material layer can be suitably formed by any suitable method, such as by means of a cyclical vapor phase deposition method such as atomic layer deposition (ALD).

During a method as disclosed herein, the substrate can be maintained at any suitable pressure. For example, the substrate can be maintained at a pressure which may be less than 760 Torr or between 0.2 Torr and 760 Torr, about 1 Torr and 100 Torr, or about 1 Torr and 10 Torr, or about 0.5 Torr and 10 Torr, or less than 3 Torr, or less than 2 Torr, or less than 1 Torr.

In some embodiments, the method further comprises a step of annealing the substrate.

In some embodiments, annealing the substrate can be carried out at a temperature of at least 200° C. to at most 500° C., or at a temperature of at least 300° C. to at most 400° C., for example at a temperature of 325° C., 350° C., or 375° C.

The anneal can be performed, for example, in an inert atmosphere or in an oxidizing atmosphere. Suitable inert atmospheres include noble gasses such as Ar and He. Suitable oxidizing atmospheres include gasses or gas mixtures comprising an oxygen-containing gas such as O₃ and O₂.

In some embodiments, the step of forming the proximal material layer is preceded by annealing substrate. Accordingly, the material quality of the high-k dielectric layer and the dipole layers can be improved without subjecting the proximal material layer to the same heat treatment.

An exemplary anneal can be carried out for a duration of at least 5 minutes to at most 20 minutes, for example for 10 or 15 minutes.

In some embodiments, forming the dipole layers, forming the high-k dielectric layer, and the annealing step can be carried out in the same processing chamber. Doing so can advantageously enhance at least one of throughput and material quality.

In some embodiments, a method as described herein is carried out in a system comprising a first processing chamber and a second processing chamber. In such embodiments, forming the dipole layers, forming the high-k dielectric layer, and a subsequent step of annealing these layers can be carried out in the first processing chamber. Then, the proximal material layer can be formed in the second processing chamber.

In some embodiments, a method as described herein is carried out in a system that comprises a first processing chamber, a second processing chamber, and a third processing chamber. In such embodiments, forming the dipole layers and the high-k dielectric layer can be carried out in the first processing chamber, the step of annealing can be carried out in the second processing chamber, and the step of forming the proximal material layer can be carried out in the third processing chamber. Optionally, the distal material layer can also be formed in the third processing chamber, or in a fourth processing chamber. Suitably, the distal material layer can be formed prior to formation dipole layers and the high-k dielectric layer. Suitably, the system can comprise a robotic transport system that is arranged to transport substrates between the processing chambers, without any intervening vacuum break.

In some embodiments, the substrate can be annealed at a temperature of less than 800° C. For example, in some embodiments of the disclosure, the anneal can be carried out at a temperature between approximately 20° C. and approximately 800° C., about 100° C. and about 500° C., about 150° C. and about 450° C., or about 200° C. and about 400° C., or about 200° C. and about 250° C., or about 250° C. and about 300° C., or about 300° C. and about 350° C., or about 350° C. and about 400° C.

In some embodiments, annealing the substrate can be done before forming the proximal dipole layer and after forming the high-k dielectric layer. In some embodiments, annealing the substrate can be done after forming the proximal dipole layer and before forming the proximal material layer. In some embodiments, annealing the substrate can be done after forming the proximal material layer.

Further described is a system that comprises one or more processing chambers, a hafnium precursor source that comprises a hafnium precursor, a zirconium precursor source that comprises a zirconium precursor, a dipole precursor source that comprises a dipole precursor, an oxygen reactant source that comprises an oxygen reactant, and a controller. The controller is configured to control gas flow into the one or more processing chambers and to process a substrate by means of a method as described herein.

In some embodiments, distal dipole layer, forming the high-k dielectric, and forming the proximal dipole layer is done in a single reaction chamber, without any intervening vacuum break. For example, all of the distal dipole layer, high-k dielectric, and proximal dipole layer can be formed by means of a cyclical deposition technique such as atomic layer deposition.

FIGS. 1A-1D show four band diagrams. In particular, FIG. 1A shows a band diagram of an ideal metal-insulator-metal (MIM) structure (110), FIG. 1B shows a band diagram of an MIM structure (120) in which the insulator comprises bulk defects, FIG. 1C shows a band diagram of an MIM structure (130) comprising n-type dipole layers (134,135), and FIG. 1D shows a band diagram of an MIM structure (140) comprising p-type dipole layers (144,145). It shall be understood that, in line with common practice in the Art, the band diagrams are given in terms of electron energy levels.

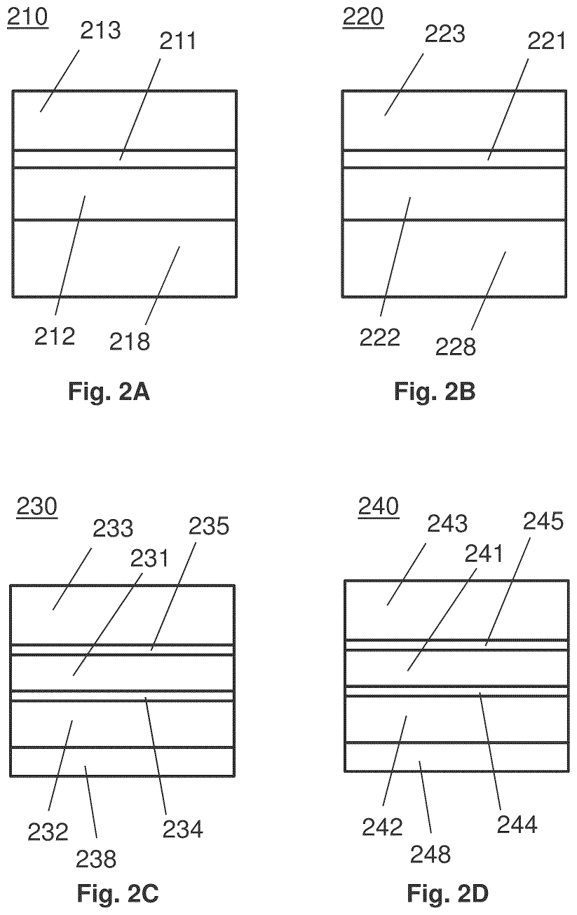

FIGS. 2A-2D schematically shows the physical structures that give rise to the band diagrams of FIGS. 1A-1D. In particular, FIGS. 2A-2D show four structures. FIG. 2A shows an ideal MIM structure (210), FIG. 2B shows a non-ideal MIM structure (220) in which the insulator comprises bulk defects, FIG. 2C shows an MIM structure (230) that comprises n-type dipole layers (234,235), and FIG. 2D shows an MIM structure (240) that comprises p-type dipole layers (244,245).

The ideal MIM structure (210) comprises a distal contact (212) and a proximal contact (213). The distal contact (212) and the proximal contact (213) can have an identical or substantially identical composition. Alternatively, the distal contact (212) and the proximal contact (213) can have a different composition. The ideal MIM structure (210) further comprises a dielectric layer (211). The dielectric layer (211) is ideal in the sense that it does not comprise any traps. The dielectric layer (211) is positioned in between the distal contact (212) and the proximal contact (213). In some embodiments, at least one of the distal contact and the proximal contact are selected from titanium nitride, cobalt, ruthenium, molybdenum, tungsten, iridium, platinum, and ruthenium oxide.

In an exemplary method of forming such a structure, the distal contact (212) is formed on a substrate (218), the dielectric layer (211) is formed on the distal contact (212), and the proximal contact (213) is formed on the dielectric layer (211).

The band diagram (110) of the ideal MIM structure (210) is shown in FIG. 1A. The band diagram (110) is shown in the absence of bias, so the Fermi level of the distal contact (112) and the Fermi level of the proximal contact (113) are equal. The dielectric layer has a band gap (111). For the case shown, the conduction band offset is smaller than the valence band offset. Thus, the dielectric forms a less effective barrier for electrons than for holes, in terms of thermionic emission, in terms of Fowler-Nordheim tunneling, and in terms of direct tunneling, such that electrons have a higher contribution to the leakage current than holes in this structure.

The non-ideal MIM structure (220) is similar to its ideal counterpart (210): it also comprises a distal contact (222), a proximal contact (223), and a dielectric layer (221) as before. This notwithstanding, the dielectric layer (221) is non-ideal in the sense that it comprises traps.

A non-ideal MIM structure (220) can be formed in the same way as the ideal MIM structure (210).

The band diagram (120) of the non-ideal MIM structure (220) is shown in FIG. 1B. The band diagram (120) is shown in the absence of bias, so the Fermi level of the distal contact (122) and the Fermi level of the proximal contact (123) are equal. The dielectric layer has a band gap (121). Again in this example, the conduction band offset is smaller than the valence band offset. Thus, the dielectric forms a less effective barrier for electrons than for holes, both in terms of thermionic emission over the dielectric barrier and in terms of direct tunneling through the dielectric barrier, such that electrons have a higher contribution to the leakage current than holes in this structure. In addition, there are traps (129) in the band gap (121) of the dielectric. These traps give rise to additional states in the forbidden region of the dielectric which in turn give rise to further leakage current mechanisms, in particular Poole-Frenkel emission and trap-assisted tunneling. In the example shown, the defect states are located in the upper part of the band gap of the dielectric layer, such that they contribute more to the electron leakage current through the dielectric layer than to the hole leakage current through the dielectric layer. Thus, for the case shown, the leakage current through the dielectric layer is dominated by an electron current.

An MIM structure (230) that comprises n-type dipole layers (234,235) is shown in FIG. 2C. The corresponding band diagram (130) is shown in FIG. 1C. The MIM structure (230) of FIG. 2C particularly comprises a substrate (238), a distal contact (232), a proximal contact (233), and a dielectric layer (231). As before, the dielectric layer (231) is located in between the distal contact (232) and the proximal contact (233). This notwithstanding, n-type dipole layers (234,235) are provided between the dielectric layer (231) and the contacts (232,233). In particular, a distal n-type dipole layer (234) is provided between the dielectric layer (231) and the distal contact (232), and a proximal n-type dipole layer (235) is provided between the dielectric layer (231) and the proximal contact (233). The n-type dipole layers (234,235) each contain a dipole. The dipoles are oriented in such a way that they give rise to electric dipole fields which point towards the dielectric layer, i.e. such that the electrical potential decreases towards the dielectric layer. This results in upwards shifting of the band structure of the dielectric layer (231) vis-à-vis the contacts (232), as shown in FIG. 1C.

FIG. 1C shows the band structure (130) of a structure (230) according to FIG. 2C, in terms of electron energy levels. In the embodiment shown, the Fermi levels (132,133) of the proximal and distal contacts are equal, which corresponds to zero applied bias. In comparison to the structure (120) of FIG. 1B, the bands (131) of the dielectric layer are shifted upwards. This is caused by the presence of n-type dipole layers and their built-in electric fields. The bands (134,135) of the n-type dipole layers rise towards the dielectric layer. As a result, the leakage current through the dielectric layer decreases since the leakage current of electrons through the dielectric is reduced by the n-type dipole induced upwards band bending. Without wishing to be bound by any particular theory or mode of operation, it is believed that this leakage current reduction is caused by a reduction one or more of direct electron tunneling, Fowler-Nordheim electron tunneling, trap-assisted electron tunneling, thermionic emission, and Poole-Frenkel Emission of electrons.

An MIM structure (230) that comprises p-type dipole layers (244,245) is shown in FIG. 2C. The corresponding band diagram (140) is shown in FIG. 1D. The MIM structure (240) of FIG. 2C particularly comprises a substrate (248), a distal contact (242), a proximal contact (243), and a dielectric layer (241). As before, the dielectric layer (241) is located in between the distal contact (242) and the proximal contact (243). This notwithstanding, p-type dipole layers (244,245) are provided between the dielectric layer (241) and the contacts (242,243). In particular, a distal p-type dipole layer (244) is provided between the dielectric layer (241) and the distal contact (242), and a proximal p-type dipole layer (245) is provided between the dielectric layer (241) and the proximal contact (243). The p-type dipole layers (244,245) each contain a dipole. The dipoles are oriented in such a way that they give rise to electric dipole fields which point away from the dielectric layer, i.e. such that the electrical potential increases towards the dielectric layer. This results in downwards shifting of the band structure of the dielectric layer (241) vis-à-vis the contacts (242), as shown in FIG. 1D.

FIG. 1D shows the band structure (140) of a structure (240) according to FIG. 2D, in terms of electron energy levels. In the embodiment shown, the Fermi levels (142,143) of the proximal and distal contacts are equal, which corresponds to zero applied bias. In comparison to the structure (120) of FIG. 1B, the bands (141) of the dielectric layer are shifted downwards. This is caused by the presence of p-type dipole layers and their built-in electric fields. The bands (144,145) of the n-type dipole layers drop down towards the dielectric layer. As a result, the leakage current through the dielectric layer increases since the leakage current of electrons through the dielectric is increased by the decreased barrier height resulting from the p-type dipole induced downwards band bending. Such a situation is undesirable when the structure is used in a capacitor. This notwithstanding, such a structure can be useful as a carrier-selective contact, in particular an electron-selective contact, when at least one of the proximal contact and the distal contact comprises a semiconductor. Carrier-selective contacts can be used in the context of minority carrier devices such as solar cells.

Whereas FIGS. 1A-1D and 2C show a structure and band structure for dielectrics that have a smaller conduction band offset than a valence band offset, similar structures can be employed for reducing, or altering, the leakage current of structures with dielectrics that have a smaller valence band offset than conduction band offset. In that case, p-type dipoles can be gainfully employed for increasing the valence band offset to reduce the leakage current, which can be useful for making capacitors. Also, n-type dipoles, leading to upwards band bending, can, in conjunction with at least one of the distal and proximal electrode comprising a semiconductor, be gainfully employed to manufacture carrier-selective contacts, in particular hole-selective contacts, which can be useful for making minority carrier devices, such as solar cells.

In an exemplary embodiment, a structure according to the embodiment of FIG. 2C can be formed as follows: p-type monocrystalline silicon is used as a substrate (238). The distal electrode (232) can comprise 60 nm of tungsten adjacent to the substrate, and 5 nm titanium nitride on the tungsten. A high-k dielectric layer (231) such as hafnium oxide can be employed. The thickness of the dielectric layer can be around 1.9 nm. A distal n-type dipole layer (234) can be located between the distal electrode (232) and the dielectric layer (231). A proximal n-type dipole layer (234) can be located on the proximal side (i.e. the top of the dielectric layer in FIG. 2C of the dielectric layer. The proximal electrode (233) can comprise 5 nm TiN adjacent to the proximal n-type dipole layer (234). The proximal electrode (233) can further comprise 60 nm of tungsten on the TiN layer. Tungsten can be deposited using CVD or ALD. TiN can be deposited using ALD or CRD. The n-type dipole layers can be deposited using ALD. The dielectric layer can be deposited using ALD.

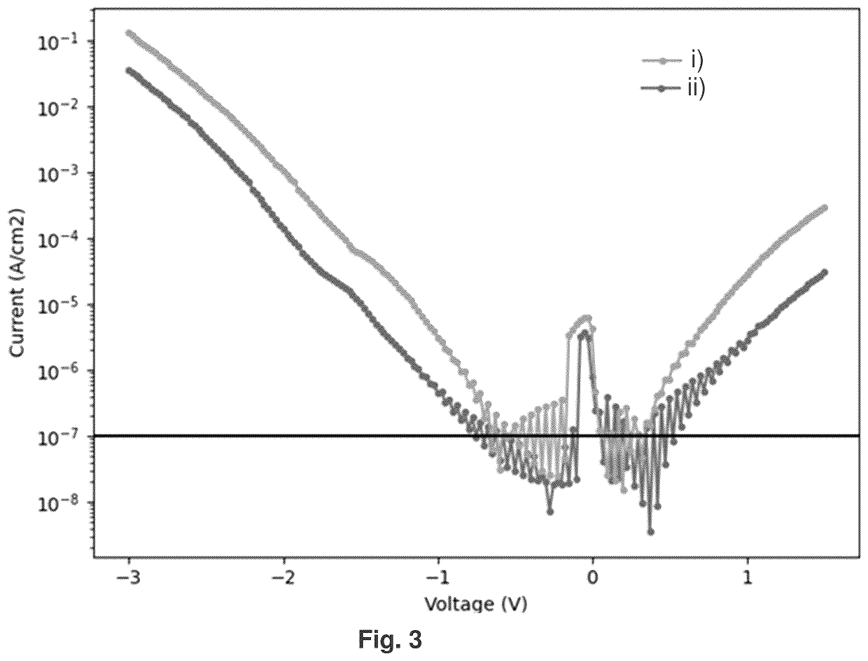

FIG. 3 shows experimental current-voltage (IV) characteristics obtained on a structure without dipole layers (lighter curve i), and on a structure with n-type dipole layers (darker curve ii)), i.e. on a structure according to the general form of FIG. 2C. Both structures are metal-insulator-metal (MIM) capacitors. In particular, the structure that was used for measurement ii) comprises a distal electrode comprising titanium nitride which is formed on an oxidized silicon wafer, the substrate. A lanthanum oxide distal dipole layer is formed on the distal electrode, and a hafnium zirconium oxide dielectric is formed on the lanthanum oxide dipole layer. A lanthanum oxide proximal dipole layer is formed on the dielectric layer, and a titanium nitride layer electrode is formed on the lanthanum oxide proximal dipole layer. Advantageously, the leakage current through the capacitor is reduced when n-type dipole layers are used, compared to the case without dipole layers. Transmission electron microscopy measurements (TEM) advantageously indicated no increase of insulator thickness for the structure with n-type dipole layers, compared to the structure without n-type dipole layers.

The sample without dipole layer comprised the following steps: The high-k dielectric was formed by depositing hafnium zirconium oxide using atomic layer deposition. The atomic layer deposition process comprised a plurality of cycles. Each cycle comprised a hafnium precursor pulse, followed by an oxygen reactant pulse, followed by a zirconium precursor pulse, followed by an oxygen reactant pulse. The hafnium precursor was Tetrakis(ethylmethylamido)hafnium. The zirconium precursor was Tetrakis(ethylmethylamido)zirconium.

The sample with dipole layer was made as follows: the distal dipole layer was made using atomic layer deposition of lanthanum oxide, which comprises 3 ALD cycles. Each ALD cycle comprised a lanthanum precursor pulse and an oxygen reactant pulse. The lanthanum precursor used was a heteroleptic lanthanum precursor comprising two alkyl-substituted isopropyl ligands and an N,N′-diisopropylacetamidinate ligand as described elsewhere herein. The high-k dielectric was formed by depositing hafnium zirconium oxide using atomic layer deposition. The atomic layer deposition process comprised a plurality of cycles. Each cycle comprised a hafnium precursor pulse, followed by an oxygen reactant pulse, followed by a zirconium precursor pulse, followed by an oxygen reactant pulse. The hafnium precursor was Tetrakis(ethylmethylamido)hafnium. The zirconium precursor was Tetrakis(ethylmethylamido)zirconium. The proximal dipole layer was made using atomic layer deposition of lanthanum oxide, which comprises 3 ALD cycles. Each ALD cycle comprised a lanthanum precursor pulse and an oxygen reactant pulse. For each layer, ozone was used as the oxygen reactant. The proximal and distal material layers comprised titanium nitride.

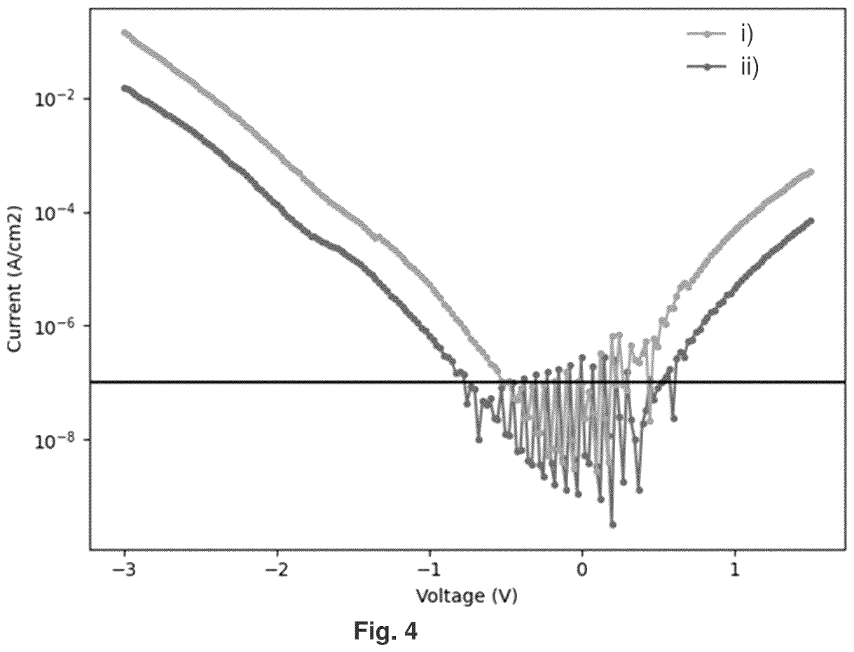

FIG. 4 shows experimental current-voltage (IV) characteristics obtained on a structure without dipole layers (lighter curve i), and on a structure with n-type dipole layers (darker curve ii)), i.e. on a structure according to the general form of FIG. 2C. Both structures are metal-insulator-metal (MIM) capacitors. The structure that was used for measurement ii) of FIG. 4 has the same structure as the structure that was used for measurement ii) of FIG. 3, except that the structure that was used for FIG. 4 measurement ii) comprises cerium oxide (CeO₂) dipole layers instead of lanthanum oxide (La₂O₃) dipole layers. Cerium oxide and lanthanum oxide dipole layers are examples of n-type dipole layers. Again, the leakage current through the capacitor is advantageously reduced when the n-type dipole layers are used, compared to the case without dipole layers. Transmission electron microscopy measurements (TEM) advantageously indicated no increase of insulator thickness for the structure with n-type dipole layers, compared to the structure without n-type dipole layers.

The sample without the dipole layer was made in the same way as explained in the context of the embodiment of FIG. 3.

The sample with dipole layer was made as follows: the distal dipole layer was made using atomic layer deposition of cerium oxide, which comprises 3 ALD cycles. Each ALD cycle comprised a cerium precursor pulse and an oxygen reactant pulse. The cerium precursor was tris(isopropylcyclopentadienyl)cerium(III). The high-k dielectric was formed by depositing hafnium zirconium oxide using atomic layer deposition. The atomic layer deposition process comprised a plurality of cycles. Each cycle comprised a hafnium precursor pulse, followed by an oxygen reactant pulse, followed by a zirconium precursor pulse, followed by an oxygen reactant pulse. The hafnium precursor was Tetrakis(ethylmethylamido)hafnium. The zirconium precursor was Tetrakis(ethylmethylamido)zirconium. The proximal dipole layer was made using atomic layer deposition of cerium oxide as for the distal dipole layer, and comprised 3 ALD cycles. Each ALD cycle comprised a cerium precursor pulse and an oxygen reactant pulse. For each layer, ozone was used as the oxygen reactant.

The experiments shown in FIGS. 3 and 4, carried out with La₂O₃ and Ce₂O₃ dipole layers, respectively, show ^{˜}10× leakage reduction when the dipole layers are integrated into TiN/dipole/HfZrO₂/dipole/TiN MIMCAP structures. The dielectric constant of TiN/La₂O₃/HfZrO₂/La₂O₃/TiN reaches as high as 62. TEM was done to evaluate thickness increase and exact same thickness was observed in samples with or without dipoles. This means that the dipole layer does not result in any thickness increase, and effectively acts as a zero thickness interface engineering layer. Energy-dispersive x-ray analysis (EDX) at 880 k magnification on the samples with La dipole also does not detect any La signal, further supporting the zero thickness of the dipole layer.

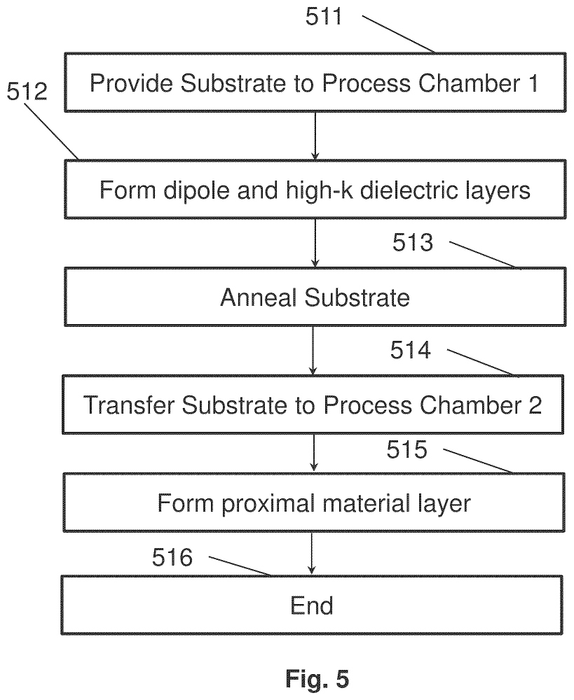

In an exemplary embodiment, reference is made to FIG. 5. FIG. 5 shows an embodiment of a method as described herein. The method comprises a step (511) of providing a substrate to a first processing chamber. Then, the method comprises a step (512) of consecutively forming a distal dipole layer, a high-k dielectric layer, and a proximal dipole layer on the substrate. In a further step (513), the substrate is subjected to an annealing step. For example, the substrate can be annealed in a substantially inert annealing ambient comprising a noble gas. Other suitable annealing ambients include oxygen-containing ambients such as O₂-containing ambients. Suitably, the anneal can be carried out at an annealing temperature of at least 300° C. to at most 500° C., or of at least 350° C. to at most 450° C., for example at a temperature of around 400° C. After the anneal, the substrate can be transferred (514) to a second process chamber. The second process chamber can be a dedicated process chamber, or another chamber such as a load lock. Suitably, the first process chamber and the second process chamber can be comprised in the same vacuum system such that processes can be carried out on substrates in the first process chamber and the second process chamber without any intervening vacuum break, i.e. processes can be processed in the first process chamber and in the second process chamber without exposure of the substrate to atmospheric air in between the processes in the first process chamber and the second process chamber. In the second process chamber, a proximal material layer can be formed on the substrate in a further step (515). Suitable proximal material layers can, for example, be formed using an atomic layer deposition process and include semiconducting oxides such as indium-gallium-zinc-oxide (IGZO), indium-tin-oxide (ITO), nickel oxide (NiO), and cuprous oxide (Cu₂O). Thus, the dipole layers and the high-k dielectric layer can be given a heat treatment to improve its properties without subjecting the top electrode to a heat treatment which might harm its properties. After the step (515) of forming the proximal material layer, the method ends (516), and the substrate can be subjected to further processing steps, if desired.

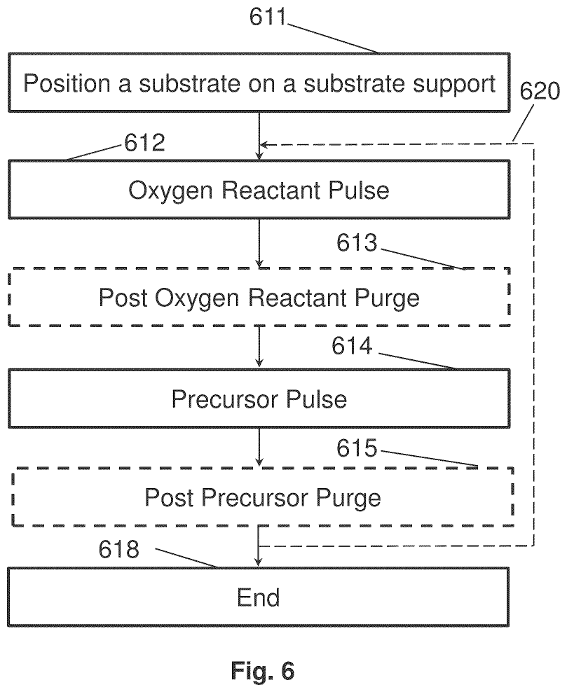

FIG. 6 schematically shows a process flow of an embodiment of a method for forming a dipole layer or for forming a high-k dielectric as described herein. The method comprises a step (611) of positioning a substrate on a substrate support. Then, the method comprises executing (612) an oxygen reactant pulse. The oxygen reactant pulse comprises exposing the substrate to an oxygen reactant. Any suitable oxygen reactant as described herein can be used during the oxygen reactant pulse. Suitable oxygen reactants include oxygen-containing reactants such as O₂ and O₃, oxygen and hydrogen containing reactants such as H₂O and H₂O₂, and oxygen and nitrogen containing reactants such as N₂O, and NO, and NO₂. Optionally, a post oxygen reactant purge (613) is then carried out. The post oxygen reactant purge (613) comprises exposing the substrate to an oxygen reactant. Then, the method comprises executing (614) a precursor pulse. The precursor pulse comprises a step of exposing the substrate to a precursor. Depending on whether or not a distal dipole layer, a high-k dielectric layer, or a proximal dipole layer is formed, the precursor can be a distal dipole precursor, a high-k dielectric precursor, or a proximal dipole precursor. Suitable precursor are described herein. After the precursor pulse (614), the method optionally comprises executing (615) a post precursor purge. The oxygen reactant pulse (612), the precursor pulse (614), and their respective optional purges (613, 615) are optionally repeated (620) one or more times until a material having a desired thickness has been deposited. After a material having a desired thickness has been deposited, the method ends (618).

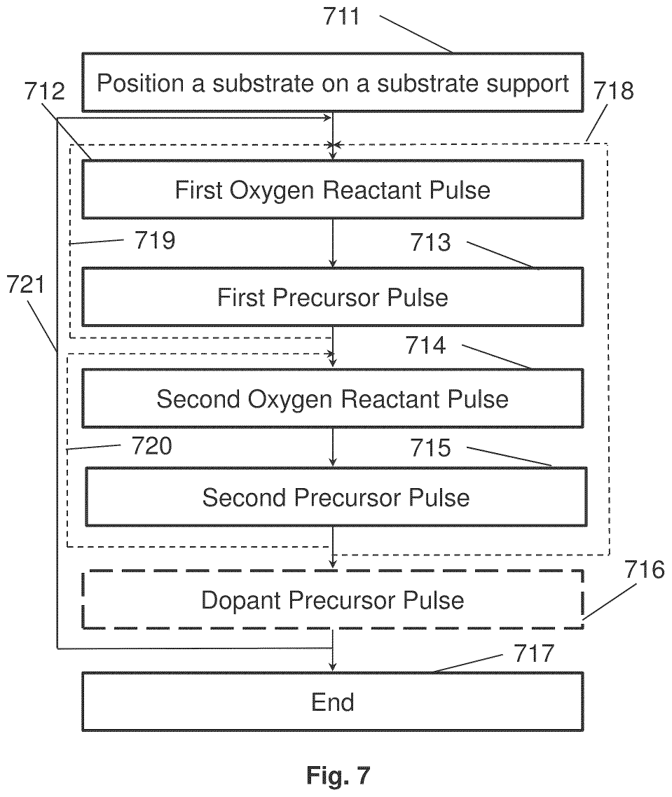

FIG. 7 schematically shows a process flow according to another embodiment of a method as described herein. FIG. 7 specifically shows how a high-k dielectric comprising hafnium, zirconium, and oxygen can be formed. The method comprises a step (711) of positioning a substrate on a substrate support.

Then, the method comprises executing (712) a first oxygen reactant pulse. The first oxygen reactant pulse comprises exposing the substrate to a first oxygen reactant. Any suitable oxygen reactant as described herein can be used during the first oxygen reactant pulse. Then, the method comprises executing (713) a first precursor pulse. The first precursor pulse comprises a step of exposing the substrate to a first precursor. Suitable first precursors include hafnium precursors or zirconium precursors as described herein. The oxygen reactant pulse (712) and the first precursor pulse (713) form a first sub cycle (719) which can optionally be repeated (719) one or more times.

Then, the method of the embodiment of FIG. 7 comprises executing (714) a second oxygen reactant pulse. The second oxygen reactant pulse (714) comprises exposing the substrate to a second oxygen reactant. Any suitable oxygen reactant as described herein can be used during the second oxygen reactant pulse. Then, the method comprises executing (715) a second precursor pulse. The second precursor pulse (715) comprises a step of exposing the substrate to a second precursor.

Suitable second precursors include hafnium precursors and zirconium precursors as described herein. It shall be understood that the first precursor and the second precursor are different. The first oxygen reactant and the second oxygen reactant can be the same or they can be different. The second oxygen reactant pulse (714) and the second precursor pulse (715) form a second sub cycle (720) which can optionally be repeated (720) one or more times.

The one or more first sub cycles (719) and the one or more second sub cycles (720) together form a deposition cycle (718). The deposition cycle (718) can optionally be repeated one or more times. Then, an optional dopant precursor pulse (716) can be carried out. The dopant precursor pulse (716) comprises exposing the substrate to a dopant precursor. Suitable dopant precursors can comprise n-type or p-type dipole precursors as described herein. Additionally or alternatively, the dopant precursor can comprise an element comprised in a material layer. Note that optionally, a purge can be executed after one or more of the pulses executed in an embodiment of the presently described method of FIG. 7.

The one or more deposition cycles (718) and the optional dopant precursor pulse (716) together form a super cycle (721). Optionally, the super cycle (721) is repeated one or more times. After a suitable amount of super cycles (721) have been carried out, the method ends (717).

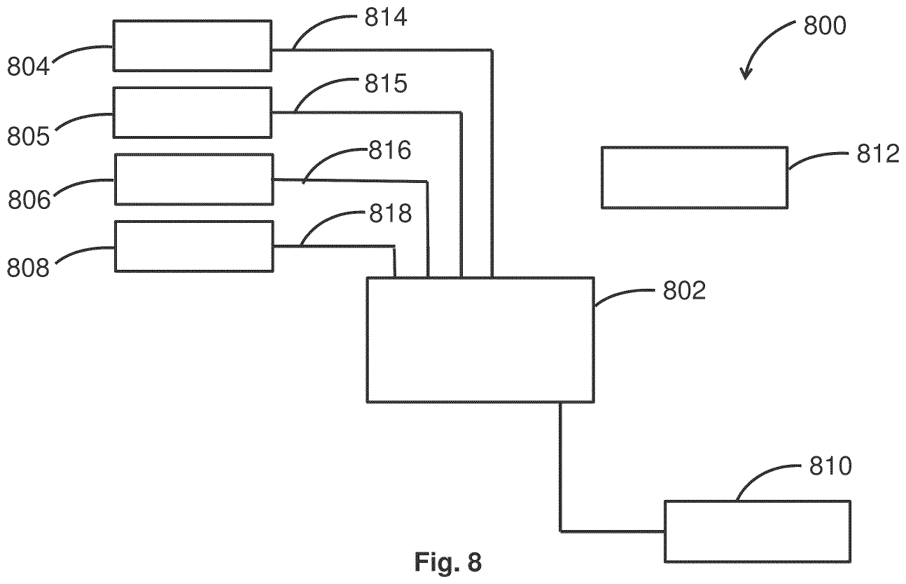

FIG. 8 illustrates a system (800) in accordance with exemplary embodiments of the disclosure. The system (800) can be configured to perform a method as described herein and/or form a structure or device portion as described herein.

In the illustrated example, the system (800) includes one or more reaction chambers (802), a high k dielectric precursor gas source (804), a dipole precursor gas source (806), an oxygen reactant gas source (808), an exhaust (810), and a controller (812). In some embodiments, the system further comprises one or more of a second high-k dielectric precursor gas source (not shown) and a second dipole precursor gas source (not shown). The reaction chamber (802) can include an ALD reaction chamber.

The first precursor gas source (804) can include a vessel and one or more precursors as described herein-alone or mixed with one or more carrier (e.g., noble) gases. The dopant precursor gas source (806) can include a vessel and one or more dopant precursors as described herein-alone or mixed with one or more carrier gases. The oxygen reactant gas source (808) can include one or more oxygen reactants as described herein.

Although illustrated with four gas sources (804)-(808), the system (800) can include any suitable number of gas sources. The gas sources (804)-(808) can be coupled to the reaction chamber (802) via lines (814)-(818), which can each include flow controllers, valves, heaters, and the like. The exhaust (810) can include one or more vacuum pumps.

The controller (812) includes electronic circuitry and software to selectively operate valves, manifolds, heaters, pumps and other components included in the system (800). Such circuitry and components operate to introduce precursors, reactants, and purge gases from the respective sources (804)-(808).

The controller (812) can control timing of gas pulse sequences, temperature of the substrate and/or reaction chamber, pressure within the reaction chamber, and various other operations to provide proper operation of the system (800). The controller (812) can include control software to electrically or pneumatically control valves to control flow of precursors, reactants and purge gases into and out of the reaction chamber (802). The controller (812) can include modules such as a software or hardware component, e.g., a FPGA or ASIC, which performs certain tasks. A module can advantageously be configured to reside on the addressable storage medium of the control system and be configured to execute one or more processes as described herein.

Other configurations of the system (800) are possible, including different numbers and kinds of precursor and oxygen reactant sources and optionally further including purge gas sources. Further, it will be appreciated that there are many arrangements of valves, conduits, precursor sources, and purge gas sources that may be used to accomplish the goal of selectively feeding gases into the reaction chamber (802). Further, as a schematic representation of a system, many components have been omitted for simplicity of illustration, and such components may include, for example, various valves, manifolds, purifiers, heaters, containers, vents, and/or bypasses.

During operation of the system (800), substrates, such as semiconductor wafers (not illustrated), are transferred from, e.g., a substrate handling system to the reaction chamber (802). Once the substrate(s) are transferred to the reaction chamber (802), one or more gases from the gas sources (804)-(808), such as precursors, reactants, carrier gases, and/or purge gases, are introduced into the reaction chamber (802).

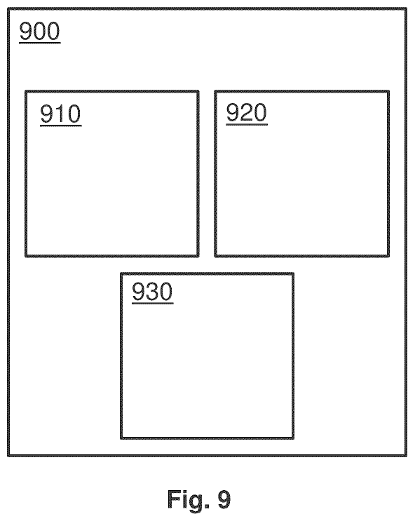

In a further example, reference is made to FIG. 9. FIG. 9 schematically shows a system (900) comprising a first process chamber (910), a second process chamber (920), and a third process chamber (930). The first process chamber (910) can be arranged for forming at least one of a distal material layer and a proximal material layer. The second process chamber (920) can be arranged for forming a distal dipole layer, a high-k dielectric layer, and a proximal dipole layer on a substrate. The third process chamber (930) can comprise one or more heating elements such as resistive heaters and infrared lamps.

In some embodiments, a system according to FIG. 9 can be employed for forming a structure as described herein.

After the anneal, a proximal material layer be formed on the proximal dipole layer in the third process chamber (930). Suitably, the proximal material layer can be formed using a cyclical deposition process such as atomic layer deposition. The proximal material layer can comprise a metal or semiconductor. For example, the proximal material layer can comprise a semiconducting oxide. Suitable material layers are described elsewhere herein. In some embodiments, the third process chamber (930) can, additionally or alternatively, function as a load lock. For example, the third process chamber (930) can comprise a robot arm. Thus, throughput can be enhanced while minimizing the system's footprint.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A structure comprising
a proximal material layer;
a proximal dipole layer adjacent to the proximal material layer;
a high-k dielectric adjacent to the proximal dipole layer;
a distal dipole layer adjacent to the high-k dielectric; and,
a distal material layer adjacent to the distal dipole layer.

2. The structure according to claim 1 wherein electric potential decreases towards the high-k dielectric.

3. The structure according to claim 1 wherein electric potential increases towards the high-k dielectric.

4. The structure according to claim 1 wherein the proximal dipole layer and the distal dipole layer comprise an element selected from a list consisting of element selected from the list consisting of magnesium (Mg), erbium (Er), strontium (Sr), scandium (Sc), yttrium (Y), lanthanum (La), and cerium (Ce).

5. The structure according to claim 1 wherein the proximal dipole layer and the distal dipole layer comprise an element selected from a list consisting of vanadium (V), aluminum (Al), nickel (Ni), and tin (Sn).

6. A method of forming a structure, the method comprising
providing a substrate to a reaction chamber, the substrate comprising a distal material layer;
forming a distal dipole layer on to the distal material layer;
forming a high-k dielectric on the distal dipole layer; and,
forming a proximal dipole layer on the high-k dielectric.

7. The method according to claim 6 wherein forming the distal dipole layer comprises executing a distal dipole cyclical deposition process, wherein the distal dipole cyclical deposition process comprises one or more distal dipole cycles, wherein a distal dipole cycle comprises consecutively executing a distal dipole precursor pulse and a distal dipole oxidant pulse, wherein the distal dipole precursor pulse comprises contacting the substrate with a distal dipole precursor, and wherein the distal dipole oxidant pulse comprises contacting the substrate with a distal dipole oxidant.

8. The method according to claim 7 wherein the distal dipole cyclical deposition process comprises from at least 3 to at most 5 distal dipole cycles.

9. The method according to claim 7 wherein forming the proximal dipole layer comprises executing a proximal dipole cyclical deposition process, wherein the proximal dipole cyclical deposition process comprises one or more proximal dipole cycles, wherein a proximal dipole cycle comprises consecutively executing a proximal dipole precursor pulse and a proximal dipole oxidant pulse, wherein the proximal dipole precursor pulse comprises contacting the substrate with a proximal dipole precursor, and wherein the proximal dipole oxidant pulse comprises contacting the substrate with a proximal dipole oxidant.

10. The method according to claim 9 wherein the proximal dipole cyclical deposition process comprises from at least 3 to at most 5 proximal dipole cycles.

11. The method according to claim 9 wherein at least one of the distal dipole precursor and the proximal dipole precursor is selected from a scandium precursor, a lanthanum precursor, a cerium precursor, and an yttrium precursor.

12. The method according to claim 6 further comprising a step of annealing the substrate.

13. The method according to claim 9 wherein at least one of the distal dipole precursor and the proximal dipole precursor comprises one or more precursors selected from a list consisting of a vanadium precursor, an aluminum precursor, a nickel precursor, and a tin precursor.

14. The method according to claim 9 wherein at least one of the distal dipole precursor and the proximal dipole precursor comprises one or more precursors selected from a list consisting of a scandium precursor, a strontium precursor, a lanthanum precursor, a cerium precursor, and an yttrium precursor.

15. The method according to claim 6 wherein the method further comprises a step of forming a proximal material layer on the proximal dipole layer.

16. The structure according to claim 1 wherein at least one of the distal dipole layer and the proximal dipole layer comprises a material selected from a list consisting of scandium oxide, strontium oxide, lanthanum oxide, cerium oxide, and yttrium oxide.

17. The structure according to claim 1 wherein at least one of the distal dipole layer and the proximal dipole layer comprises a material selected from a list consisting of aluminum oxide, vanadium oxide, tin oxide, and nickel oxide.

18. The structure according to claim 1 wherein at least one of the distal material layer and the proximal material layer comprises a transition metal nitride.

19. A system comprising:
one or more processing chambers;
a hafnium precursor source comprising a hafnium precursor;
a zirconium precursor source comprising a zirconium precursor;
a dipole precursor source comprising a dipole precursor;
an oxygen reactant source comprising an oxygen reactant; and,
a controller,
wherein the controller is configured to control gas flow into the one or more processing chambers and to process a substrate by:
providing a substrate to a reaction chamber, the substrate comprising a distal material layer;
forming a distal dipole layer on to the distal material layer;
forming a high-k dielectric on the distal dipole layer; and,
forming a proximal dipole layer on the high-k dielectric.

20. The system according to claim 19 wherein forming the distal dipole layer, forming the high-k dielectric, and forming the proximal dipole layer is done in a single reaction chamber, without any intervening vacuum break.
